(19) United States
(12) Patent Application Publication
(10) Pub. No.: US 2011/0108773 A1
(43) Pub. Date: May 12, 2011

(54) Compositions for Depositions and Processing of Films for Electronic Applications

(75) Inventor: Makarand P. Gore, Fort Collins, CO (US)

(73) Assignee: YewSavin, Inc., Fort Collins, CO (US)

(21) Appl. No.: 12/941,602

(22) Filed: Nov. 8, 2010

Related U.S. Application Data
(60) Provisional application No. 61/259,535, filed on Nov. 9, 2009.

(51) Int. Cl. H01B 1/12; F21V 9/00; B05D 5/12; B05C 9/12; H01L 31/18; H01L 39/00

(52) U.S. Cl. 252/501.1; 252/582; 427/532; 118/620; 438/57; 505/100; 257/E31.001

(57) ABSTRACT

Methods and systems disclosed herein involve conversion of precursors to electronic films with many properties such as conductor, resistor, semiconductor, photovoltaic, insulator and optical conversion films. There are a large number of materials such as transition metal oxides, metals, combination oxides that may be deposited as organic precursors and subsequently processed by radiated energy. In practice of the systems and methods disclosed herein, the films are processed by a “matched” radiation to either intrinsic absorption of the film precursors, or due to an added absorber to the film precursors. Since many of the precursors have been previously described as “Metal-Organic” precursors, the process can be described as “Metal-Organic Deposition by Enhanced Light-Absorption” (MODEL-A).

### CROSS REFERENCE

This application claims benefit to U.S. Provisional Application No. 61/259,535, entitled “Compositions for Depositions and Processing of Films for Electronic Applications”, filed Nov. 9, 2009, which is incorporated herein by reference in its entirety.

### TECHNICAL FIELD

The present disclosure is generally related to production of films for electronic applications, and more particularly related to production of electronic components by digital printing and parallel processing of precursor materials.

### BACKGROUND

The advance of digital printing methods has opened up opportunities for use in high-precision manufacturing. Digital application of fluids and conversion to electronic films using processes such as drying by heat, or by physical transformations such as structural changes due to fusion, and chemical transformations such as photo-thermal decomposition using radiation, are used in deposition of electronic films (e.g. Metal Organic Chemical Vapor Deposition (MOCVD)). A particularly powerful and fast emerging technology is combination of digital printing of MOVCD precursors followed by conversion to electronic films. Following the digital printing, the film formation is induced by exposure to energy, either by direct bulk, or blackout heating in chambers and towers, or by a complete swath of radiation across the media, heating major portion of film and substrates. There are examples of blackout pattern energy delivery (as in case of IR or xenon lamp) delivery, and there is examples of digital delivery of energy registering a pattern on a “full-bleed” black out films of materials (such as photolithography of circuits, and direct to plate processes). Extremely fast, precise and controlled deposition of precursor films in the digital delivery methods in all methods described so far is followed by conventional delivery of energy for drying, curing or setting the film precursors. For example, the energy is delivered to an entire surface under exposure, and in many cases the entire chamber using lamps and hot air currents, regardless of the fact that the film is only 1/100^{th} to 1/10^{th} of the mass requiring heating. Further the typical average coverage area in any printing is 50% of the total surface area. The energy needs for film formation (drying, fusing etc.) processes in modern devices is greater than 50% of the total energy required. With the acute environmental, energy and cost concerns, and need for better process controls, there is a severe unmet need for effective and efficient energy delivery methods in preparation of electronic films.

### SUMMARY

Example embodiments of the present disclosure provide electronic film precursor compositions and methods for high efficiency absorption of radiation, and electronic films formed thereof. Briefly described, in architecture, one example embodiment of the composition, among others, can be implemented as follows: at least one metal organic or electronic film precursor, the precursor composition configured to absorb radiation at a wavelength of a particular radiated energy.

Embodiments of the present disclosure can also be viewed as providing methods for high efficiency absorption of radiation precursors, and electronic films formed thereof. In this regard, one embodiment of such a method, among others, can be broadly summarized by the following steps: depositing a composition on a substrate, the composition comprising a metal organic or electronic film precursor; and irradiating the composition with a particular wavelength, the precursor having been selected to absorb radiation at the particular wavelength.

### BRIEF DESCRIPTION OF DRAWINGS

FIG. 1 provides illustrations of example embodiments of effecting radiation wavelength, and absorber wavelength.

FIG. 2 provides an example embodiment of a scheme for deposition of silver films.

FIG. 3 provides example embodiments of structures of absorbers with corresponding maximum absorption wavelength band.

FIG. 4 provides example embodiments of systems for use of ink compositions containing a “matched” absorber.

### DETAILED DESCRIPTION

Embodiments of the present disclosure will be described more fully hereinafter with reference to the accompanying drawings in which like numerals represent like elements throughout the several figures, and in which example embodiments are shared. Embodiments of the claims may, however, be embodied in many different forms and should not be construed to be limited to the embodiments set forth herein. The examples set forth herein are non-limiting examples, and are merely examples among other possible examples. The term “matched band” is defined as the match between the absorption band of the precursors or films, and the emission band of the radiation source; which may have less than 100 nm difference in the wavelengths at full-width, half max band of absorption and emission spectrum. The term “precursor for electronic films” is defined as one of a mixture of components that result in materials with properties suitable for inclusion in electronic devices such as resistance, electrical conductance, capacitance, semi-conductance, transparent conductance, and heat conductance. The term absorber and ‘antenna’ may be used synonymously. The term electronic films is defined as a deposition of materials in any shape or form, including materials such as metals, chalcogenides, alloys, nano-material composites, insulators, transparent conductors, metal oxides including those used in CMOS devices.

An absorber with significant absorbance matching the processing radiation is included in the compositions for efficient capture of energy. Embodiments of the present disclosure can also be viewed as providing compositions that have a functional film precursor such as an ink that might include electronic film precursors, and an absorber that is capable of absorbing a radiation wavelength that is “matched” to the waveband of the processing radiation. The graphs in FIG. 1 show the illustrations of effecting wavelength, absorber wavelength, which may be the result of intrinsic absorbance of the precursor materials or an added absorber. The Morse code line graph of the ink of this disclosure shows the precursor combination with two functional wavelengths of absorption, one for the visual range and another at 780 nm for effecting radiation absorption. The solid line graph shows the emission frequencies of the radiation source, in this case a 780 nm LED LASER. The absorption band is overlapped with the radiation band; at OD of 1.5, more than 90% radiation at 780 nm band is absorbed.

Recently, we have disclosed that the most efficient form of delivery is to supply “Energy on Demand”. This disruptive process DIGITALLY delivers the energy “beam” to only specific areas of the medium covered by the film precursors “locations” or films. The word digitally is defined as any process where the deposition is composed of placing film precursor in a restricted area, and the area covered is addressed by a raster controlled signal e.g. a bit.

This can be accomplished by activating a radiation source such as a high power LED, LASER diode or lamp focused on a pixel (bitmap) of the film covered area. In case of the practice of this EOD where heating is the mechanism for film processing, the film precursors absorb at least 20% of the radiation energy. In a more preferred case, the film precursors must absorb 50% of the radiant energy. In the most preferred case, the film precursors must absorb 80% or more of the energy delivered by the source. For these requirements to be met, the film precursors are required to have at least one absorption band that is matched to at least one band of the emission source and absorbs at least 20% of the radiation or OD of 0.2 in precursor form. A “matched” band is defined as having less than 100 nm difference in the wave lengths at full-width half max band of absorption of film and emission spectrum of the source. This method is used in this disclosure for conversion of precursors to electronic films with many properties such as conductor, resistor, semiconductor, photovoltaic, insulator and optical conversion films. There are a large number of materials such as transition metal oxides, metals, combination oxides that are deposited as organic or inorganic precursors and subsequently processed by heat. In practice of the systems and methods disclosed herein, the films are processed by a “matched” radiation to either intrinsic absorption of the film precursors, or due to an added absorber to the film precursors. Since many of the precursors have been previously described as “Metal-Organic” precursors, the process can be described as “Metal-Organic Deposition by Enhanced Light-Absorption” (MODEL-A). The materials (and resulting products) used in practice of this invention include any materials that are used in deposition of electronic films such as resistors, conductors, inductors, capacitors, super-conductors and the like. Although metal organic precursors offer advantages in solubility in non-polar solvents, inorganic precursors also can be used for deposition. These include but are not limited to the precursors and chemistries shown in table 1.

TABLE 1
Non-limiting Examples of Precursors, chemistries and products in
practice of MODEL-A.

| Precursor | Product | Application |
|---|---|---|
| Yittirbium Oxalate, Erbium | Y2O3:Yb:Er oxide | Infra red to visible |
| Oxalate, Yttirium Oxalate | | light conversion |
| Er, Yb, Tm, Trifluoroacetate | Er, Yb, Tm fluorides | Infrared to visible up- |
| | on NaYF4 Nano- | conversion |
| | particles | |
| Silver (1,5-Cyclooctadiene), | Silver metal | Conductive, metallic |
| 1,1,1,5,5,5-hexafluoro-2,4- | | silver films |
| pentanedionate | | |
| (Ag(COD)hfac) | | |
| Metallic powders | Metallic films | Conductors |
| | Precursors | |
| Silver Stearte | Silver Metal | Conductive films, |
| | | Dispersant for |
| | | metallic powders |
| Silver 1,1,1-trifluoro-2,4- | Silver Metal | Silver films |
| pentanedione trialkyl phosphite | | |
| (tfac)Ag(P(OAlkyl)3). | | |
| Alkyl = Methly,Ethyl, iso-propyl | | |
| Silver 3,6,9- | Silver Metal | Jet-able inks for |
| Trioxaundecanedioic acid | | silver deposition |
| Silver 3,6,9-Trioxadecanoic | Silver metal | Jet-able inks for |
| acid | | silver deposition |
| Silver 1,1,1,5,5,5-hexafluoro- | Silver Metal | Silver films |
| 2,4-pentanedione trialkyl | | |
| phosphite | | |
| (hfac)Ag(P(OAlkyl)3). | | |
| Alkyl = Methly, Ethyl,iso-propyl | | |
| Copper Formate | Copper metal | Copper conductors, |
| | | films |
| 1,1,1,5,5,5-hexafluoro-2,4- | Copper film | Copper conductors, |
| pentanedione Copper (I) | | films |
| trimethylvinyl silane | | |
| (Cu(hfac)tmvs) | | |
| 1,1,1,5,5,5-hexafluoro-2,4- | Copper film | Copper conductors |
| pentanedione Copper (I) | | |
| trimethoxylvinyl silane | | |
| (Cu(hfac)tmvs) | | |
| Titanium iso-propoxide | TiO2 | Metal Oxide, |
| Ti(OiPr)4 | | Resistors, Matrix |
| Zr[N(C2H5)2]4 | ZrO2 | Metal Oxide |
| Zr[OC(CH3)3]4 | ZrO2 | Metal Oxide |
| (C5H5)2Zr(CH3)2 | ZrO2 | Metal Oxide |
| (C5H5)2Zr(CH3)2; Co(C5H5)2 | ZrO2—Co2O3 | Metal Oxide |
| (mixture) | | |
| (C5H5)2Zr(CH3)2; Mn(hfac)2 | ZrO2—MnOx | Metal Oxide |
| (CH3)2Al(OiPr) | Al2O3 | Dielectric |
| R₂₍Al)-Acetylacetone, R = Alkyl | Al2O3 | Dielectric |
| Allyl(Methylcyclopentadienyl) | Platinum Metal | Metallic Film |
| platinum | | |
| HB(Pz)3Cu(PCy3) | Copper metal | Conductors |
| Ni(dmg)2 | Nickel Metal or | Nickel or Oxide films, |
| | oxide | or Nickel Alloys |
| Ni(MeCp)2 | Nicekel metal or | Nickel or Oxide films, |
| | oxide | or Nickel Alloys |
| Ni(hfa)2 | Nickel metal or | Nickel or Oxide films, |
| | oxide | or Nickel Alloys |
| Fe(Cp)2 | Iron Oxide | Ferrites |
| Triethylamine Alane | Aluminum metal | Al film |
| bis(2,2,6,6-tetramethyl-3,5- | Nickel Metal | Nickel Metal or alloy |
| heptandionato)Ni(II), | | |
| N,Ne-ethylenebis(2,4- | Nickel Metal | Nickel metal or alloy |
| pentandion-iminoato)Ni(II) | | |
| bis(2-amino-pent-2-en-4- | Nickel metal | Nickel metal or alloy |
| onato)Ni(II) | | |
| Indium Acetylacetone | InO | Transparent |
| | | Conductors |
| Tin Acetylaacetone | | SnOₓ Transparent |
| | | conductors |
| Dialkyl Zinc | ZnO | Transparent |
| | | conductors, Piezo- |
| | | materials, LEDs |
| Zn-MOPD bis(2-methoxy-6- | ZnO | Transparent |
| methyl-3,5- | | conductors, Piezo- |
| heptanedionato)zinc(II)- | | materials, LEDs |
| Silver Neodecanoate | Ag metal | Conductors, |
| | | (Combination) |
| | | Resistors |
| Copper Neodecanoate | Copper metal | Conductors, alloy films |
| gold amine (imidazole) 2- | Gold film | Conductors |
| ethyl hexanoate | | |
| gold tert.docyl mercaptide | Gold film | Conductors, Alloys |
| Strontium Ethoxide | Strontium Oxide | Mixture Ferroelectric |
| | | oxides |
| Tantalum Ethoxide | Tantalum Oxide | Mixture Ferroelectric |
| | | oxides |
| Triphenyl Bismuth | Bismuth Oxide | Mixture Ferroelectric |
| | | oxides |
| Palladium-2-ethylhexanoate | Palladium Oxide | Silver-Palladium Resistors |
| Manganese-2ethylhexanoate | Mn metal | Ag—Mn oxide |
| | | Resistors |
| barium complex of 2,2,6,6- | BaOx | Mixture in |
| tetramethyl-3,5-heptanedione | | Superconducting |
| (Hthd) and 1,1,1,2,2,3,3- | | oxides |
| heptafluoro-7,7-dimethyl-4,6- | | |
| octanedione | | |
| TriethylGallium | Gallium | Photovoltaic |
| | Semiconductor | semiconductor |
| Trimethyl Indium | Indium | Photovoltaic |
| | Semicondutor | semiconductor |
| Dimethyl Zinc | Zinc semiconductor | Photovoltaic |
| | | semiconductor |

Additional examples of such materials include: silver-palladium oxide resistors; ruthenium oxide resistors; barium ruthenate resistors; barium titanate ferroelectric capacitors and piezoelectric elements; lead titanateizirconate ferroelectrics; spinel-type ferrites such as magnetite; hexaferrites; and garnet-type ferrites. Thick film resistor inks may be used to print resistors rather than bonding discrete components to the circuit. Silver-palladium mixtures, which can be oxidized to silver-palladium metal and semiconducting palladium oxide, have been widely used as resistive films as described by Larry, J. R; Rosenberg, R. M.; Uhier, R. O.; in Trans IEEE, CHMT-3, (2), 211-225, 1980. In recent years semiconducting ruthenium oxide compositions are preferred. Thick film capacitors have been prepared by printing a metallic plate, printing a layer of thick film ferroelectric dielectric, such as barium titanate, and printing another metallic plate to complete the capacitor. At high temperature the barium titanate sinters into monolithic ceramic, and grain growth occurs, improving its dielectric properties.

Superconducting materials fabricated by this method include various types of materials, such as metal oxide superconductors comprising admixtures of metals from Groups IB, IIA, and IIIB of the Periodic Table. Illustrative materials of such type include the metal oxide superconductors of the yttrium-barium-copper type (YBa2 Cu3 Oy), the so-called “123” HTSC materials, wherein y may be from about 6 to about 7.3, as well as materials where Y may be substituted by Nd, Sm, Eu, Gd, Dy, Ho, Yb, Lu, Y.sub.0.5-Sc.sub.0.5, Y.sub.0.5-La.sub.0.5, and Y.sub.0.5-Lu.sub.0.5, and where Ba may be substituted by Sr—Ca, Ba—Sr, and Ba—Ca. Some of these material are described in “High T.sub.c Oxide Superconductors,” MRS Bulletin, January, 1989, pages 20-24, and “High T.sub.c Bismuth and Thallium Oxide Superconductors,” Sleight, A. W., et al, MRS Bulletin, January, 1989, pages 45-48.

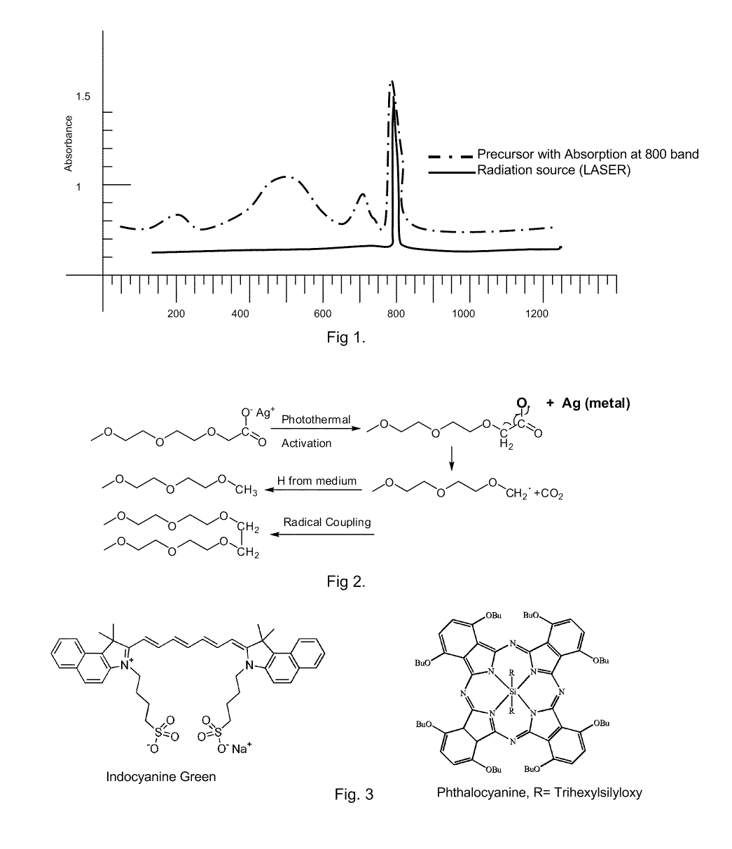

An example embodiment of a silver precursor and reaction to produce silver is shown in FIG. 2. The silver precursor was prepared from the reaction of silver nitrate with 3,6,9-Trioxadecanoic acid in presence of a base. Indo-cyanine green was chosen as the first dye due to its high extinction coefficient of 150,000 at 10 Milli-Mol concentration for 808 nm radiation. This produced ink precursor that absorbed 99% of the radiation at 0.1% w/v concentration. The absorber dye and the silver precursor are mixed at a molecular level, causing very uniform heating of the films. The chemical decomposition of inks to produce silver involves decomposition through a free radical mechanism. In the case of 3,6,9-Trioxadecanoic acid salt, the possible by-products are the corresponding polyethylene glycol (PEG) or the carboxylic acid. The PEG and the 3,6,9-Trioxadecanoic acid can be used in pharmaceutical and cosmetic formulations. Therefore, the inks prepared present no environmental hazard. FIG. 2 shows the reaction sequence in production of silver.

An example embodiment includes 22% of the silver salt, 0.1% of surfactant Surfynol 465, 0.1% Indocyanine green, and pure water. The inks had viscosity of 1.6 cps, and surface tension was 49 dyn/cm. The solutions were substantially clear with a slight green tinge. Heating of the ink films, produced by roller coated on glass using irradiation with 780 nm band LASER produced shiny silver films.

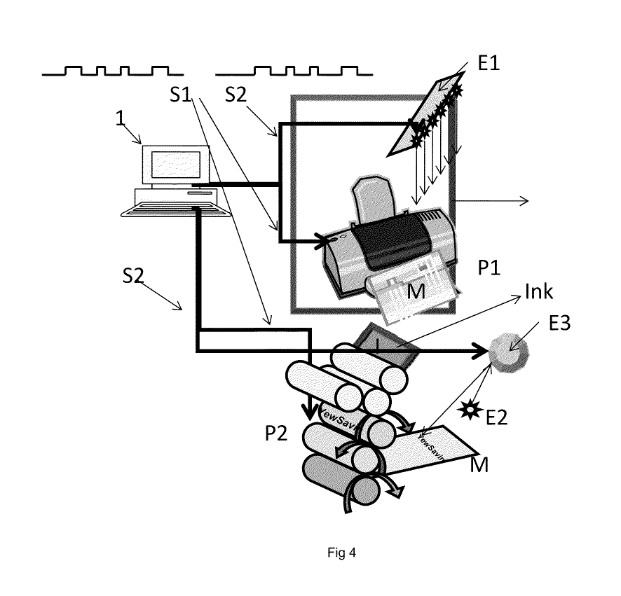

A variety of absorbers may be used in example embodiments. FIG. 3 shows two such compounds, one an indocyanine dye, and second, a phthalocyanine dye known to be stable to light. Generally, the absorption coefficients of these dyes or pigments are in excess of 100,000. Additional examples of dyes useful in practice of this disclosure are mentioned in U.S. Pat. No. 7,083,094, filed Aug. 1, 2006; incorporated herein by reference. According to one example embodiment, films or film precursors with enhanced absorption include an antenna package uniformly distributed/dissolved in at least one and preferably all phase(s) of the films or precursors in order to customize the resulting coating to a radiation at a specified wavelength and (reduced) power. The antenna dyes included in the present optional antenna package may be selected from a number of radiation absorbers such as, but not limited to, aluminum quinoline complexes, porphyrins, porphins, indocyanine dyes, phenoxazine derivatives, phthalocyanine dyes, polymethyl indolium dyes, polymethine dyes, guaiazulenyl dyes, croconium dyes, polymethine indolium dyes, metal complex IR dyes, cyanine dyes, squarylium dyes, chalcogeno-pyryloarylidene dyes, indolizine dyes, pyrylium dyes, quinoid dyes, quinone dyes, azo dyes, and mixtures or derivatives thereof. Other suitable antennas may also be used in the example systems and methods and are known to those skilled in the art and can be found in such references as “Infrared Absorbing Dyes”, Matsuoka, Masaru, ed., Plenum Press, New York, 1990 (ISBN 0-306-43478-4) and “Near-Infrared Dyes for High Technology Applications”, Daehne, Resch-Genger, Wolfbeis, Kluwer Academic Publishers (ISBN 0-7923-5101-0), both incorporated herein by reference.

In another example, antenna dyes included in the present antenna package may be selected to correspond to a radiation generated by a known radiation generating device. According to one example embodiment, the media processing system may include a radiation generating device configured to produce one or more lasers with wavelength values including, but in no way limited to, approximately 300 nm to approximately 600 nm, approximately 650 nm, approximately 780 nm, approximately 808 nm, and/or approximately 1120 nm. By selectively matching the wavelength values of the radiation generating device(s), image formation may be maximized at lower power levels. According to one exemplary embodiment, the image formation using the antenna dyes may be performed at power levels as low as 5 mW/cm2 and lower.

According to an example embodiment, antenna dyes that may be used to selectively sensitize the above-mentioned coating to a wavelength of between approximately 300 nm and 600 nm include, but are in no way limited to, cyanine and porphyrin dyes such as etioporphyrin 1 (CAS 448-71-5), phthalocyanines and naphthalocyanines such as ethyl 7-diethylaminocoumarin-3-carboxylate (.lamda. max=418 nm). Specifically, according to one exemplary embodiment, appropriate antenna dyes include, but are in no way limited to, aluminum quinoline complexes, porphyrins, porphins, and mixtures or derivatives thereof. Non-limiting specific examples of suitable radiation antenna include 1-(2-chloro-5-sulfophenyl)-3-methyl-4-(4-sulfophenyl)azo-2-pyrazolin-5-one disodium salt lamda.max=400 nm); ethyl 7-diethylaminocoumarin-3-carboxylate (.lamda. max=418 nm); 3,3′-diethylthiacyanine ethylsulfate (.lamda. max=424 nm); 3-allyl-5-(3-ethyl-4-methyl-2-thiazolinylidene)rhodanine (.lamda. max=430 nm) (each available from Organica Feinchemie GmbH Wolfen), and mixtures thereof.

Non-limiting specific examples of suitable aluminum quinoline complexes can include tris(8-hydroxyquinolinato)aluminum (CAS 2085-33-8), and derivatives such as tris(5-cholor-8-hydroxyquinolinato)aluminum (CAS 4154-66-1), 2-(4-(1-methyl-ethyl)-phenyl)-6-phenyl-4H-thiopyran-4-ylidene)-propanedin-itril-1,1-dioxide (CAS 174493-15-3), 4,4′-[1,4-phenylenebis(1,3,4-oxadiazole-5,2-diyl)]bis N,N-diphenyl benzeneamine (CAS 184101-38-0), bis-tetraethylammonium-bis(1,2-dicyano-dithiolto)-zinc(II) (CAS 21312-70-9), 2-(4,5-dihydronaphtho[1,2-d]-1,3-dithiol-2-ylidene)-4,5-dihydro-naphtho[1-,2-d]1,3-dithiole, all available from Syntec GmbH.

Non-limiting examples of specific porphyrin and porphyrin derivatives may include etioporphyrin 1 (CAS 448-71-5), deuteroporphyrin IX 2,4 bis ethylene glycol (D630-9) available from Frontier Scientific, and octaethyl porphrin (CAS 2683-82-1), azo dyes such as Mordant Orange (CAS 2243-76-7), Methyl Yellow (CAS 60-11-7), 4-phenylazoaniline (CAS 60-09-3), Alcian Yellow (CAS 61968-76-1), available from Aldrich chemical company, and mixtures thereof.

Further, in order to sensitize the above-mentioned coating to a radiation wavelength of approximately 650 nm, many indolium of phenoxazine dyes and cyanine dyes such as cyanine dye CS172491-724 may be selectively incorporated into one or more phases of the above-mentioned coating. Additionally, dyes having absorbance maximums at approximately 650 nm may be used including, but in no way limited to many commercially available phthalocyanine dyes such as pigment blue 15.

Further, example embodiments of radiation absorbing antenna dyes having absorbance maximums at approximately 650 nm according to their extinction coefficient that may be selectively incorporated into the present antenna dye package to reduce the power level initiating a color change in the coating include, but are in no way limited to, dye 724 (3H-Indolium, 2-[5-(1,3-dihydro-3,3-dimethyl-1-propyl-2H-indol-2-ylidene)-1,3-pentadien-yl]-3,3-dimethyl-1-propyl-, iodide) (.lamda. max=642 nm), dye 683 (3H-Indolium, 1-butyl-2-[5-(1-butyl-1,3-dihydro-3,3-dimethyl-2H-indol-2-ylidene)-1,3-pe-ntadienyl]-3,3-dimethyl-, perchlorate (.lamda. max=642 nm), dyes derived from phenoxazine such as Oxazine 1 (Phenoxazin-5-ium, 3,7-bis(diethylamino)-, perchlorate) (.lamda. max=645 nm), available from “Organica Feinchemie GmbH Wollen.” Appropriate antenna dyes applicable to example embodiments of the disclosed systems and methods may also include but are not limited to phthalocyanine dyes with light absorption maximum at/or in the vicinity of 650 nm.

Example embodiments of radiation absorbing antenna dyes having absorbance maximums at approximately 780 nm that may be incorporated into the present antenna dye package include, but are in no way limited to, many indocyanine IR-dyes such as IR780 iodide (Aldrich 42,531-1) (1) (3H-Indolium, 2-[2-[2-chloro-3-[(1,3-dihydro-3,3-dimethyl-1-propyl-2H-indol-2-ylidene)e-thylidene]-1-cyclohexen-1-yl]ethenyl]-3,3-dimethyl-1-propyl-, iodide (9Cl)), IR783 (Aldrich 54,329-2) (2) (2-[2-[2-Chloro-3-[2-[1,3-dihydro-3,3-dimethyl-1-(4-sulfobutyl)-2Hindol-2--ylidene]-ethylidene]-1-cyclohexen-1-yl]-ethenyl]-3,3-dimethyl-1-(4-sulfob-utyl)-3H-indolium hydroxide, inner salt sodium salt). Additionally, low sensitivity/higher stability dyes having absorbance maximums at approximately 780 nm may be used including, but in no way limited to NIR phthalocyanine or substituted phthalocyanine dyes such as Cirrus 715 dye from Avecia, YKR186, and YKR3020 from Yamamoto chemicals. Other examples of absorbers include Lumogen IR765, Lumogen IR 788 and Lumogen IR 1050 available from BASF Chemicals, Ludwigshafen, Germany.

Similarly, high sensitivity/lower stability radiation absorbing antenna dyes having absorbance maximums at approximately 808 nm that may be incorporated into the present coating include, but are in no way limited to, Indocyanine dyes such as 3H-Indolium, 2-[2-[2-chloro-3-[(1,3-dihydro-1,3,3-trimethyl-2H-indol-2-ylidene)ethylid-ene]-1-cyclopenten-1-yl]ethenyl]-1,3,3-trimethyl-, salt with 4-methylbenzenesulfonic acid (1:1) (9Cl), (Lambda max-797 nm), CAS No. 193687-61-5, available from “Few Chemicals GMBH”; 3H-Indolium, 2-[2-[3-[(1,3-dihydro-1,3,3-trimethyl-2H-indol-2-ylidene)ethylidene]-2-[(-1-phenyl-1H-tetrazol-5-yl)thiol]-1-cyclohexen-1-yl]ethenyl]-1,3,3-trimethyl-1-, chloride (9Cl), (Lambda max-798 nm), CAS No. 440102-72-7 available from “Few Chemicals GMBH”; 1H-Benz[e]indolium, 2-[2-[2-chloro-3-[(1,3-dihydro-1,1,3-trimethyl-2H-benz[e]indol-2-ylidene)-ethylidene]-1-cyclohexen-1-yl]ethenyl]-1,1,3-trimethyl-chloride (9Cl), (Lambda max-813 nm), CAS No. 297173-98-9 available from “Few Chemicals GMBH”; 1H-Benz[e]indolium, 2-[2-[2-chloro-3-[(1,3-dihydro-1,1,3-trimethyl-2H-benz[e]indol-2-ylidene)-ethylidene]-1-cyclohexen-1-yl]ethenyl]-1,1,3-trimethyl-, salt with 4-methylbenzenesulfonic acid (1:1) (9Cl), (Lambda max-813 nm), CAS No. 134127-48-3, available from “Few Chemicals GMBH”, also known as Trump Dye or Trump IR; and 1H-Benz[e]indolium, 2-[2-[2-chloro-3-[(3-ethyl-1,3-dihydro-1,1-dimethyl-2Hbenz[e]indol-2-ylid-ene)ethylidene]-1-cyclohexen-1-yl]ethenyl]-3-ethyl-1,1-dimethyl-, salt with 4-methylbenzenesulfonic acid (1:1) (9Cl) (Lambda max-816 nm), CAS No. 460337-33-1, available from “Few Chemicals GMBH”

Examples of radiation absorbers that are suitable for use in the infrared range can include, but are not limited to, polymethyl indoliums, metal complex IR dyes, indocyanine green, polymethine dyes such as pyrimidinetrione-cyclopentylidenes, guaiazulenyl dyes, croconium dyes, cyanine dyes, squarylium dyes, chalcogenopyryloarylidene dyes, metal thiolate complex dyes, bis(chalcogenopyrylo)polymethine dyes, oxyindolizine dyes, bis(aminoaryl)polymethine dyes, indolizine dyes, pyrylium dyes, quinoid dyes, quinone dyes, phthalocyanine dyes, naphthalocyanine dyes, azo dyes, hexfunctional polyester oligomers, heterocyclic compounds, and combinations thereof. Several specific polymethyl indolium compounds are available from Aldrich Chemical Company and include 2-[2-[2-chloro-3-[2-(1,3-dihydro-1,3,3-trimethyl-2H-indol-2-ylidene)-ethyl-lidene]-1-cyclopenten-1-yl-ethenyl]-1,3,3-trimethyl-3H-indolium perchlorate; 2-[2-[2-Chloro-3-[2-(1,3-dihydro-1,3,3-trimethyl-2H-indol-2-ylidene)-ethyl-lidene]-1-cyclopenten-1-yl-ethenyl]-1,3,3-trimethyl-3H-indolium chloride; 2-[2-[2-chloro-3-[(1,3-dihydro-3,3-dimethyl-1-propyl-2H-indol-2-ylidene)e-thylidene]-11-cyclohexen-1-yl]ethenyl]-3,3-dimethyl-1-propylindolium iodide; 2-[2-[2-chloro-3-[(1,3-dihydro-1,3,3-trimethyl-2H-indol-2-ylidene-)ethylidene]-1-cyclohexen-1-yl]ethenyl]-1,3,3-trimethylindolium iodide; 2-[2-[2-chloro-3-[(1,3-dihydro-1,3,3-trimethyl-2H-indol-2-ylidene)ethylid-ene]-1-cyclohexen-1-yl]ethenyl]-1,3,3-trimethylindolium perchlorate; 2-[2-[3-[(1,3-dihydro-3,3-dimethyl-1-propyl-2H-indol-2-ylidene)ethylidene-+2-(phenylthio)-1-cyclohexen-1-yl]ethenyl]-3,3-dimethyl-1-propylindolium perchlorate; and mixtures thereof. Alternatively, the radiation absorber may be an inorganic compound, e.g., ferric oxide, carbon black, selenium, or the like. Polymethine dyes or derivatives thereof (such as a pyrimidinetrione-cyclopentylidene), squarylium dyes (such as guaiazulenyl dyes), croconium dyes, or mixtures thereof may also be used. Suitable infrared sensitive pyrimidinetrione-cyclopentylidene radiation absorbers may include, for example, 2,4,6(1H,3H,5H)-pyrimidinetrione 5-[2,5-bis[(1,3-dihydro-1,1,3-dimethyl-2H-indol-2-ylidene)ethylidene]cycl-opentylidene]-1,3-dimethyl-(9Cl) (S0322 available from Few Chemicals, Germany).

In other embodiments, a radiation absorber can be included that preferentially absorbs wavelengths in the range from about 600 nm to about 720 nm and more specifically at about 650 nm. Non-limiting examples of suitable radiation absorbers for use in this range of wavelengths can include indocyanine dyes such as 3H-indolium, 2-[5-(1,3-dihydro-3,3-dimethyl-1-propyl-2H-indol-2-ylidene)-1,3-pentadien-yl]-3,3-dimethyl-1-propyl-iodide), 3H-indolium, 1-butyl-2-[5-(1-butyl-1,3-dihydro-3,3-dimethyl-2H-indol-2-ylidene)-1,3-pe-ntadienyl]-3,3-dimethyl-perchlorate, and phenoxazine derivatives such as phenoxazin-5-ium, 3,7-bis(diethylamino)perchlorate. Phthalocyanine dyes such as silicon 2,3-napthalocyanine bis(trihexylsilyloxide) and matrix soluble derivatives of 2,3-napthalocyanine (both commercially available from Aldrich Chemical), matrix soluble derivatives of silicon phthalocyanine (as described in Rodgers, A. J. et al., 107 J. Phys. Chem. A 3503-3514, May 8, 2003), matrix soluble derivatives of benzophthalocyanines (as described in Aoudia, Mohamed, 119 J. Am. Chem. Soc. 6029-6039, Jul. 2, 1997), phthalocyanine compounds such as those described in U.S. Pat. Nos. 6,015,896 and 6,025,486 (which are each incorporated herein by reference), and Projet NP800, Projet 900NP, and Project 830NP, phhthalocyanine dyes and Projet 830LDI, a polymethine dye available from Fujifilm Imaging Colorants, Manchester, England, may also be used.

In still other embodiments, a radiation source, such as a laser or LED, that emits light having blue and indigo wavelengths ranging from about 380 nm to about 420 nm may be used. In particular, radiation sources such as the lasers used in certain DVD and laser disk recording equipment emit energy at a wavelength of about 405 nm. Radiation absorbers that most efficiently absorb radiation in these wavelengths may include, but are not limited to, aluminum quinoline complexes, porphyrins, porphins, and mixtures or derivatives thereof. Some specific examples of suitable radiation absorbers suitable for use with radiation sources that output radiation between 380 and 420 nm include 1-(2-chloro-5-sulfophenyl)-3-methyl-4-(4-sulfophenyl)azo-2-pyrazolin-5-on-e disodium salt; ethyl 7-diethylaminocoumarin-3-carboxylate; 3,3′-diethylthiacyanine ethylsulfate; 3-allyl-5-(3-ethyl-4-methyl-2-thiazolinylidene)rhodanine (each available from Organica Feinchemie GmbH Wolfen), and mixtures thereof. Other examples of suitable radiation absorbers include aluminum quinoline complexes such as tris(8-hydroxyquinolinato)aluminum (CAS 2085-33-8) and derivatives such as tris(5-cholor-8-hydroxyquinolinato)aluminum (CAS 4154-66-1), 2-(4-(1-methyl-ethyl)-phenyl)-6-phenyl-4H-thiopyran-4-ylidene)-propanedin-itril-1,1-dioxide (CAS 174493-15-3), 4,4′-[1,4-phenylenebis(1,3,4-oxadiazole-5,2-diyl)]bis N,N-diphenyl benzeneamine (CAS 184101-38-0), bis-tetraethylammonium-bis(1,2-dicyano-dithiolto)-zinc(II) (CAS 21312-70-9), 2-(4,5-dihydronaphtho[1,2-d]-1,3-dithiol-2-ylidene)-4,5-dihydro-naphtho[1--,2-d]1,3-dithiole, all available from Syntec GmbH. Other examples of specific porphyrin and porphyrin derivatives can include etioporphyrin 1 (CAS 448-71-5), deuteroporphyrin IX 2,4 bis ethylene glycol (D630-9) available from Frontier Scientific, and octaethyl porphrin (CAS 2683-82-1), azo dyes such as Mordant Orange CAS 2243-76-7, Methyl Yellow (60-11-7), 4-phenylazoaniline (CAS 60-09-3), Alcian Yellow (CAS 61968-76-1), available from Aldrich chemical company, and mixtures thereof.

A variety of radiation sources as shown in Table 1. In addition to conventional IR, Xenon and UV lamps may be used in example embodiments of the systems and methods disclosed herein.

TABLE 1
Light sources:

| | | | Wavelengths | Source | |
|---|---|---|---|---|---|
| Company | Part Number | Part Name | Choice | Dimensions | Power |
| Northrop | ASM232C040 | GOLDEN | 790 to 980, | 9.6 cm × | 40 W CW |
| Grumman | | BULLET | with +/−3 nm | 0.25 cm Bar | |
| | | SUBMODULE | FWHM | | |
| Northrop | ASM232P200 | GOLDEN | 790 to 980, | 9.6 cm × | 200 W |
| Grumman | | BULLET | with +/−3 nm | 0.25 cm Bar | QCW |
| | | SUBMODULE | FWHM | | |
| Coherent | ONYX MCCP | 9010 Series | 808 nm, | 11 mm array | 2000 W to |
| | 9010-HDPKG | HD array | 915 nm, | width, 1.6 mm | 4500 W |
| | | 1.6 mm pitch | 940 nm, | pitch Pump | CW |
| | | | 975 nm | Array | |
| Coherent | 532-8 V or | Prisma 532-V | 532 nm | 0.6 mm | 12 W |
| | 532 14 V | | | | |
| SANYO | DL-7146- | Blue-Violet | 405 nm | 0.6 mm, down | 85 mw |
| | 101S | Laser diode | | to 300 nm | |
| | | | | collimated | |
| SANYO | DL-3147-060 | Red Laser | 650 nm | 0.6 mm, down | 7 mw |
| | | diode | | to 1 micron | |
| | | | | collimated | |
| SHARP | GH04125A2A | Blue-Violet | 405 nm | 0.2 mm down | 125 mw |
| | | Laser diode | | to 300 nm | |
| | | | | collimated | |
| SONY | SLD433S4 | 60 W array | 405 nm | 7.7 mm, 24° | 60 W |
| | | Laser diode | | Perpendicular | |
| | | | | and 8° | |
| | | | | parallel | |
| | | | | divergence | |
| Nichia | NCSU034A | Surface | 385 nm | 2.1 mm | 330 mw |
| | | mount UV | | | |
| | | LED | | | |
| CryLas | FQCW 266 | DP/CW/SS | 266 nm | 0.6 mm | 70 W |
| | | Laser | | | |
| Omicron | LED MOD | LEDMOD lab | 17 bands | Optical Fiber | 300 mw to |
| Laser | series | series | between | coupled, | 27 W |
| | | | 255 nm to 950 nm | 1 mm or 2 mm | |
| | | | | diameter | |

In another example embodiment, a system for parallel processing and exposure of films is used. FIG. 4 provides a system diagram for an example embodiment of a system configuration for the digitally controlled EOD system and processes. The complete details of such systems are described in patent application Ser. No. 12/912,116 filed Oct. 26, 2010, entitled “Systems and Methods of Energy on Demand Processing of Films” assigned to YewSavin, inc., incorporated herein by reference. In one example design embodiment, computer 1 is connected to a print mechanism such as an inkjet printer P1 or an offset mechanism P2, and a light source E1, through electrical signal and power control cables S1 and S2. The inks I of the inkjet or offset system may have high absorbance in the radiation band produced by sources E1 and E2. The energy from source E2 may be delivered with rotating mirror E3. The process of EOD comprises the sending of signals for printing through S1; and sending a synchronous, asynchronous or a delay added signal to light sources E1 and E2. Signal S1 causes the deposition of high absorbance inks I or film precursors I on the media M in the desired pattern, and signal S2 causes exposure of the locations of the deposited ink and film precursors. In cases where the position of deposition and exposure points are distant, an optional time delay corresponding to the time interval of travel between the deposition points to exposure point may be present in (raster) signal S1 and signal S2.

In another example embodiment, absorber IR780 available from Aldrich Chemical Company, WI; Degussa silver flake, silver neodecanoate, and neodecanoic acid are mixed together using a spatula. The resulting mixture was then milled on a roll mill to give a homogeneous paste. The paste captures 780 nm radiation to fuse to a homogeneous metal film upon exposure.

In yet another example embodiment, the ink may be prepared by mixing the YKR3070 absorber available from Yamamoto Chemical, Japan, copper flake, nanometer sized spherical copper powder mixed with neodecanoic acid (−77 wt % metal) in a glove box. This premix is than further mixed on a 2-roll mill for 30 minutes in air. The gap setting on the mill was 0.006″-0.008″. The inks absorb 99% of the 405 nm radiation and completely fuse to a metal film upon exposure.

In another example, the precursor is prepared by mixing 8 parts by weight gold flake, 1 part by weight gold neodecanoate, and 1 part by weight gold amine 2-ethyl hexanoate, and 0.05 parts of Projet NP-800, available from Fuji. The mixture is combined and blended by hand in a glove box and then roll milled in air to produce a homogeneous paste. The paste produces homogeneous gold film upon exposure to 780 nm LASER radiation.

The substrates for printing are polyimide films, polysulfone films, polyester films, Teflon coated films, silicone coated films, metal foils, metal, laminate, glass, ceramic, and paper products. Kapton® ELJ is a coated polyimide film produced by DuPont. Additional polymer films are polyesters, PET, polyethylene naphthenate, polyether ketones, acrylics, polyamides, polyurethanes, polyimides, polycarbonates, polyolefins, polyamidimides, and liquid crystal polymers. Substrates also include semiconductor surfaces such as GaAs, Silicon Nitride.

Although systems and methods of the present disclosure have been described in detail, it should be understood that various changes, substitutions and alterations can be made thereto without departing from the spirit and scope of the disclosure as defined by the appended claims.

Therefore, at least the following is claimed:

1. A composition comprising:
at least one electronic film precursor, the precursor configured to absorb radiation at a wavelength of a matching band of wavelengths of radiation.

2. The composition of claim 1, further comprising an absorber, the absorber matched to a processing radiation wavelength with a full width half maximum difference of no more than approximately 100 nm.

3. The composition of claim 1, wherein the composition is configured for Atomic Layer Deposition (ALD) activated by the particular radiated energy.

4. The composition of claim 1, wherein the at least one metal electronic film precursor is deposited by at least one of spray coating, evaporation, inkjet, roller coating, screen printing, and offset printing methods.

5. The composition of claim 1, wherein the full width half maximum of a major absorbance peak of the composition is within approximately 100 nm of the emission maxima of the particular radiated energy.

6. The composition of claim 1, wherein the composition comprises organic or inorganic metallic film precursor and a radiation absorber.

7. The composition of claim 1, wherein the composition comprises metal oxide and mixed metal oxide film precursors.

8. The composition of claim 1, wherein the composition comprises metallic precursors and at least one of meta flakes, particles, and nano-particles, which are connected upon radiation to result in continuous film.

9. The composition of claim 1, wherein a deposition of the composition results in a photovoltaic film.

10. The composition of claim 1, wherein the film precursors comprise superconductor oxides precursors.

11. The composition of claim 1, wherein the film precursors comprise CMOS, PMOS, or NMOS depositing material.

12. A method comprising:
depositing a composition on a substrate, the composition comprising an electronic film precursor; and
irradiating the composition with a particular wavelength, the precursor having been selected to absorb radiation at the particular wavelength.

13. The method of claim 12, wherein the composition further comprises an absorber matched to a processing radiation wavelength with full wavelength half maximum difference of no more than approximately 100 nm.

14. The method of claim 12, wherein the irradiation is imagewise and is digitally controlled and synchronized to expose the deposited areas.

15. The method of claim 12, wherein a deposition of the composition results in a photovoltaic film.

16. The method of claim 7, wherein depositing the electronic film precursor further comprises depositing by at least one of spray coating, evaporation, inkjet, roller coating, screen printing, and offset printing methods.

17. The method of claim 7, wherein the composition comprises organic or inorganic metallic film precursors.

18. A printing system comprising:
a deposition mechanism configured for depositing a composition on a substrate; and
an irradiation source configured to irradiating the composition with a particular wavelength, the composition comprising an electronic film precursor selected to absorb radiation at the particular wavelength.

19. The printing device of claim 18, further comprising an absorber matched to a processing radiation wavelength with a full width half maximum difference of no more than approximately 100 nm.

20. The printing device of claim 18, wherein the deposition mechanism comprises at least one of spray coating, evaporation, inkjet, roller coating, screen printing, and offset printing methods.
